(19) United States
(12) Patent Application Publication
(10) Pub. No.: US 2025/0219589 A1
(43) Pub. Date: Jul. 3, 2025

(54) APPARATUS AND METHOD FOR OFFSET CALIBRATION

(71) Applicant: INDUSTRY-UNIVERSITY COOPERATION FOUNDATION HANYANG UNIVERSITY ERICA CAMPUS, Ansan-si (KR)

(72) Inventors: Jong Seok KIM, Ansan-si (KR); Wi Man YOO, Ansan-si (KR)

(21) Appl. No.: 19/026,140

(22) Filed: Jan. 16, 2025

Related U.S. Application Data
(63) Continuation of application No. PCT/KR2024/011480, filed on Aug. 5, 2024.

(30) Foreign Application Priority Data
Dec. 28, 2023 (KR) 10-2023-0194961
Mar. 25, 2024 (KR) 10-2024-0040227

(51) Int. Cl. H03F 1/30

(52) U.S. Cl. CPC H03F 1/30; H03F 2200/375

(57) ABSTRACT

An apparatus for offset calibration according to an embodiment of the present invention relates to an apparatus to compensate an offset voltage occurring in an output buffer, the apparatus for offset calibration comprises a DAC embedded amplifier that includes the output buffer, an offset calibration signal generator configured to receive a bit string signal from the outside and generate an offset calibration signal based on the bit string signal; and an offset calibration current generator which comprises a differential difference amplifier (DDA) and is configured to generate an offset calibration current compensating for the offset voltage based on the offset calibration signal.

### CROSS-REFERENCE TO RELATED APPLICATIONS

This application is a PCT Continuation By-Pass application of PCT Application No. PCT/KR2024/011480 filed on Aug. 5, 2024, in the Korean Intellectual Property Office, and additionally claims priority from Korean Application Nos. 10-2023-0194961 filed on Dec. 28, 2023 and 10-2024-0040227 filed on Mar. 25, 2024, the entire disclosures of which are incorporated herein by reference for all purposes.

### BACKGROUND

### 1. Field

The present invention relates to an apparatus and a method for offset calibration, and more particularly, to a technology for offset compensation generated in an output buffer.

### 2. Description of the Related Art

Recently, display technologies have been developed day by day in the direction of having the highest resolution such as FHD, 4K, 8K, etc. The high resolution means that a myriad of light emitting elements are included in the display, and the uniformity indicating the light output consistency of these individual light emitting elements is increasing in importance as the display continues to develop.

The uniformity of the display may be determined by various factors, but among them, an offset of the output buffer, which is one of the causes of distribution of each channel, is pointed out as a main cause of lowering the uniformity of the display. When a mismatch occurs in a transistor of the display, an output buffer offset occurs due to a mismatch of current, which deteriorates uniformity of the display.

Therefore, various methods for offset calibration of a transistor have been studied, and representatively, there is auto zeroing. However, as optimization is still insufficient, there remains a need for technology capable of optimizing offset calibration.

### SUMMARY

In order to solve the above-described problem, the present disclosure provides an apparatus and a method for offset calibration for generating an offset calibration signal based on a bit string signal input from the outside and generating an offset compensation based on the offset calibration signal current for compensating offset voltage.

An apparatus for offset calibration according to an embodiment of the present invention relates to an apparatus to compensate an offset voltage occurring in an output buffer, the apparatus for offset calibration comprises a DAC embedded amplifier that includes the output buffer; an offset calibration signal generator configured to receive a bit string signal from the outside and generate an offset calibration signal based on the bit string signal; and an offset calibration current generator which comprises a differential difference amplifier (DDA) and is configured to generate an offset calibration current compensating for the offset voltage based on the offset calibration signal.

According to one embodiment, the DAC embedded amplifier comprises an N-bit DAC embedded input stage, a first node and a second node connected to the N-bit DAC embedded input stage, and the DDA is connected in parallel with the N-bit DAC embedded input stage via a first calibration current port connected to the first node and a second calibration current port connected to the second node.

According to one embodiment, the DDA comprises a first transistor connected to the first calibration current port and a second transistor connected to the second calibration current port, wherein the first transistor and the second transistor are connected in parallel.

According to one embodiment, the DDA further comprises a third transistor positioned between ground node and third node, wherein the third node is located at the opposite ends where the first calibration current port and the second calibration current port are positioned to connect the first transistor and the second transistor.

According to one embodiment, the offset calibration current generator further comprises an M-bit R-string DAC.

According to one embodiment, the offset calibration current generator is configured to generate the offset calibration current in the DDA based on input voltage input from the outside and output voltage, wherein the output voltage is output from the M-bit R-string DAC based on the offset calibration signal and the input voltage.

According to one embodiment, the M-bit R-string DAC is configured to adjust a minimum value of an offset compensation voltage for generating an offset calibration current based on the input voltage.

According to one embodiment, the apparatus for offset calibration further comprises an offset voltage polarity unifier unifying a polarity of the offset voltage generated from the output buffer into a positive or negative polarity.

According to one embodiment, the offset calibration signal generator is configured to receive the bit string signal of which the magnitude gradually increases until the polarity of the offset voltage is inverted, and stores the bit string signal at a moment when the polarity of the offset voltage is inverted as the magnitude of the bit string signal increases, as the offset calibration signal, and the offset calibration current generator is configured to continuously generate the offset calibration current based on the stored offset calibration signal.

According to one embodiment, the DAC embedded amp further comprises a switch for inverting an offset polarity, which is controlled by the offset voltage polarity unifier.

A method for offset calibration according to an embodiment of the present invention relates to a method to compensate an offset voltage occurring in an output buffer, the method for offset calibration comprises preparing a DAC embedded amplifier including the output buffer; receiving a bit string signal from the outside and generating an offset calibration signal based on the bit string signal in an offset calibration signal generator; and generating an offset calibration current compensating for the offset voltage based on the offset calibration signal in an offset calibration current generator which comprises a differential difference amplifier (DDA).

According to one embodiment, the DAC embedded amplifier comprises an N-bit DAC embedded input stage, a first node and a second node connected to the N-bit DAC embedded input stage, and the DDA is connected in parallel with the N-bit DAC embedded input stage via a first calibration current port connected to the first node and a second calibration current port connected to the second node.

According to one embodiment, the DDA comprises a first transistor connected to the first calibration current port and a second transistor connected to the second calibration current port, wherein the first transistor and the second transistor are connected in parallel.

According to one embodiment, the DDA further comprises a third transistor positioned between ground node and third node, wherein the third node is located at the opposite ends where the first calibration current port and the second calibration current port are positioned to connect the first transistor and the second transistor.

According to one embodiment, the offset calibration current generator further comprises an M-bit R-string DAC.

According to one embodiment, the offset calibration current generator is configured to generate the offset calibration current in the DDA based on input voltage input from the outside and output voltage, wherein the output voltage is output from the M-bit R-string DAC based on the offset calibration signal and the input voltage.

According to one embodiment, the M-bit R-string DAC is configured to adjust a minimum value of an offset compensation voltage for generating an offset calibration current based on the input voltage.

According to one embodiment, the method for offset calibration further comprises unifying a polarity of the offset voltage generated from the output buffer into a positive or negative polarity in an offset voltage polarity unifier.

According to one embodiment, the generating an offset calibration signal is configured to receive the bit string signal of which the magnitude gradually increases until the polarity of the offset voltage is inverted, and stores the bit string signal at a moment when the polarity of the offset voltage is inverted as the magnitude of the bit string signal increases, as the offset calibration signal, and the generating an offset calibration current is configured to continuously generate the offset calibration current based on the stored offset calibration signal.

According to one embodiment, the DAC embedded amp further comprises a switch for inverting an offset polarity, which is controlled by the offset voltage polarity unifier.

According to the apparatus and method for offset calibration of the present invention, an offset calibration signal is generated based on a bit string signal input from the outside, and an offset compensation current is generated based on the offset calibration signal, for compensating an offset voltage.

### BRIEF DESCRIPTION OF THE DRAWINGS

FIG. 1 is a schematic diagram illustrating the structure of a general display data driver according to an embodiment.

FIG. 2 is a diagram illustrating an offset voltage according to an output of a general display data driver.

FIG. 3 is a diagram illustrating the offset voltage corresponding to the output of the display data driver when the offset is corrected using the apparatus and method for offset calibration.

FIG. 4 is a block diagram of an apparatus for offset calibration.

FIG. 5 is a schematic diagram showing a relationship between components of an apparatus for offset calibration.

FIG. 6 is a circuit diagram of a DAC embedded amp.

FIG. 7 is a schematic diagram showing an output value when an output buffer in the DAC embedded amp operates as a comparator.

FIG. 8 is a schematic diagram of an offset voltage polarity unifier.

FIG. 9 is a timing diagram illustrating a process of unifying a polarity of an offset voltage.

FIG. 10 is a graph illustrating a state in which the polarity of an offset voltage is unified.

FIGS. 11 and 12 are schematic diagrams illustrating a state in which an offset polarity inversion switch is controlled by a switch control signal CH.

FIG. 13 is a schematic diagram of an offset calibration signal generator.

FIG. 14 is a timing diagram of generation of a calibration signal in an offset calibration signal generator.

FIG. 15 is a schematic diagram of an offset calibration current generator.

FIGS. 16 and 17 are circuit diagrams illustrating a state in which an offset calibration current generator and a DAC embedded amp are connected.

FIG. 18 is a flowchart of an offset calibration method.

### DETAILED DESCRIPTION

The advantages and features of the present invention, as well as methods for achieving them, will become apparent with reference to the embodiments described below in conjunction with the accompanying drawings. However, the present invention is not limited to the embodiments disclosed herein and may be implemented in various other forms. The embodiments are provided merely to ensure a complete understanding of the disclosure and to fully convey the scope of the invention to those skilled in the art to which the invention pertains. The invention is defined solely by the scope of the claims.

The terminology used in this specification will be briefly explained, followed by a detailed description of the present invention.

The terms used in the present invention have been selected, to the extent possible, from commonly used general terms while taking into account their functions in the context of the invention. However, these terms may vary depending on the intent of practitioners in the field, relevant case law, or the emergence of new technologies. Additionally, in certain cases, terms arbitrarily chosen by the applicant may also be used; in such instances, the detailed meanings of these terms will be explicitly provided in the description of the invention. Therefore, the terminology used in the present invention should be interpreted not merely based on their names, but in light of their meanings and the overall context of the present invention.

Hereinafter, embodiments of the present invention will be described in detail with reference to the accompanying drawings to enable those skilled in the art to which the present invention pertains to practice the invention easily. For clarity in explaining the present invention, parts irrelevant to the description are omitted in the drawings.

Terms including ordinals such as “first,” “second,” and the like may be used to describe various elements, but the elements are not limited by these terms. These terms are only used to distinguish one element from another. For example, within the scope of the present invention, a “first” element may be referred to as a “second” element, and similarly, a “second” element may be referred to as a “first” element.

The term “and/or” includes combinations of multiple associated items or any one of the multiple associated items.

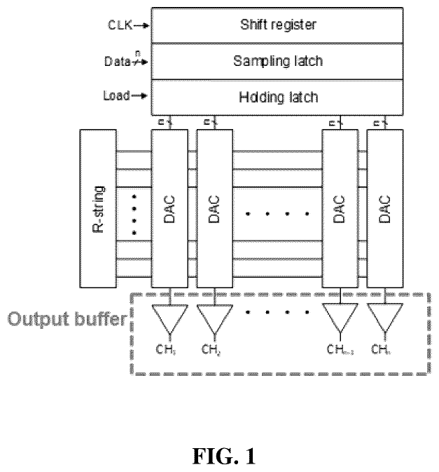

FIG. 1 is a schematic diagram illustrating the structure of a general display data driver according to an embodiment. Referring to FIG. 1, a general display data driver may include a shift register, a sampling latch, a holding latch, a digital-to-analog converter (DAC), and an output buffer.

The shift register may receive a horizontal synchronization signal and a data clock signal CLK, and sequentially generate sampling pulses while shifting the horizontal synchronization signal based on the data clock signal CLK.

The sampling latch may sequentially sample and store the data signal (Data) in response to the sampling pulse generated in the shift register.

The holding latch may simultaneously receive data stored in the sampling latch according to the data load signal (Load) and save the data.

The digital-to-analog converter may convert an input digital signal into an analog signal.

The output buffer may apply a data voltage to the data line corresponding to each channel and may serve as a buffer between the data line and the data driver.

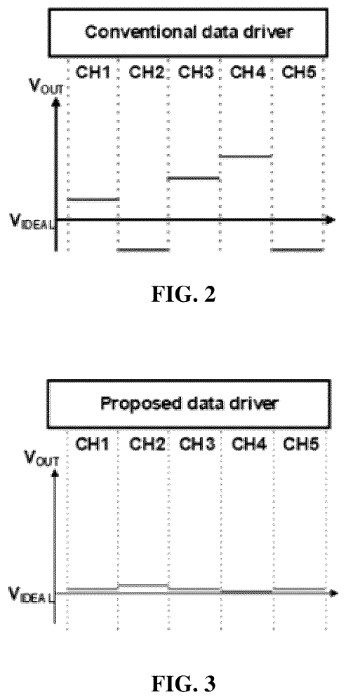

FIG. 2 is a diagram illustrating an offset voltage according to an output of a general display data driver. Referring to FIG. 2, the distribution of each channel occurs due to the offset of the output buffer, and the uniformity of the display screen deteriorates due to the distribution.

Hereinafter, an apparatus and a method for offset calibration according to the present invention will be described.

The apparatus and method for offset calibration of the present invention relate to an offset calibration apparatus and method for compensating an offset voltage generated in an output buffer. It receives a bit string signal CAL from the outside, generates an offset calibration signal TRM based on the bit string signal CAL, and generates an offset compensation current for compensating the offset voltage based on the offset calibration signal TRM while including a Differential Difference Amplifier (DDA).

The apparatus and method for offset calibration of the present invention improve the uniformity of the display screen by adding a separate device to a general display data driver, as shown in FIG. 1, to generate a current for offset compensation and correct the offset. FIG. 3 illustrates the offset voltage corresponding to the output of the display data driver when the offset is corrected using the apparatus and method for offset calibration of the present invention according to one embodiment. Comparing FIG. 2 and FIG. 3, it can be confirmed that the output voltage of the present invention's apparatus and method for offset calibration exhibits lower offset and maintains a more uniform value compared to a conventional display data driver.

Hereinafter, an apparatus for offset calibration according to an exemplary embodiment of the present invention will be described.

The apparatus for offset calibration 1 according to the present invention is preferably implemented as a circuit, but is not limited thereto.

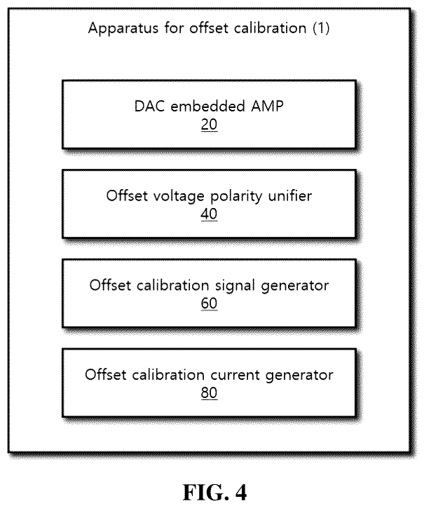

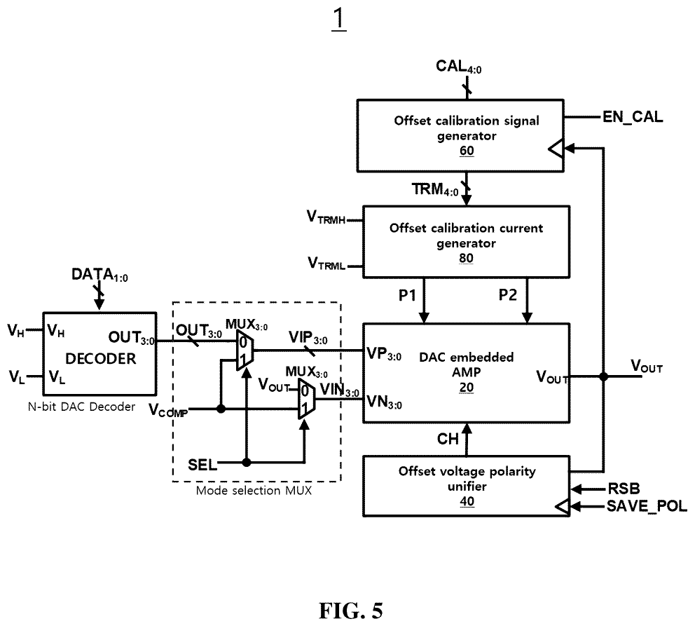

FIG. 4 is a block diagram of an apparatus for offset calibration 1 according to an exemplary embodiment of the present invention, and FIG. 5 is a schematic diagram showing a relationship between components of an apparatus for offset calibration 1 according to an exemplary embodiment of the present invention.

The apparatus for offset calibration 1 according to an embodiment of the present invention may include a DAC embedded amp 20, an offset voltage polarity unifier 40, an offset calibration signal generator 60, and an offset calibration current generator 80. In addition, an N-bit DAC decoder and a mode selection MUX may be further included. The apparatus for offset calibration 1 according to the present invention may include various configurations without limitation in addition to the above-described configurations.

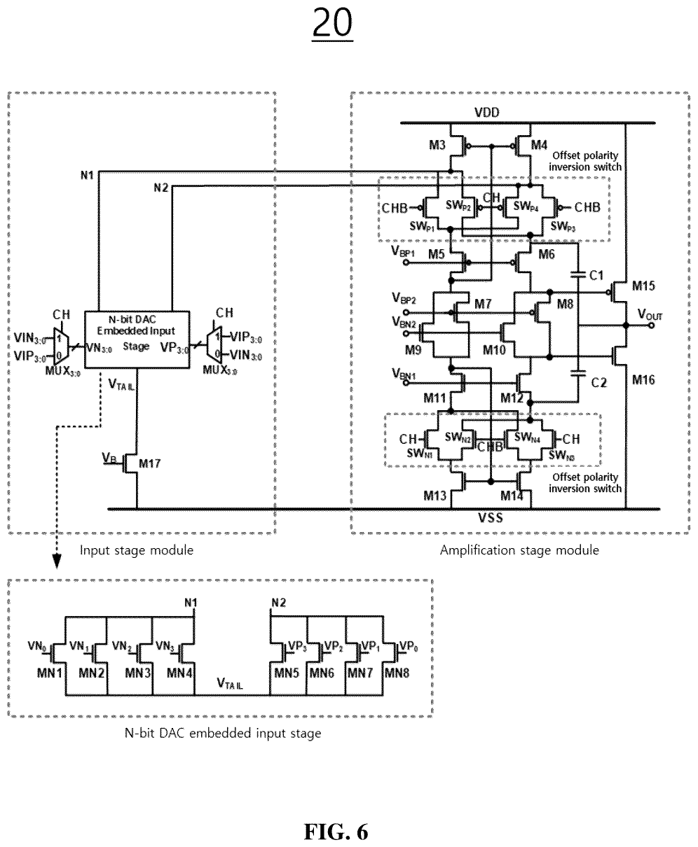

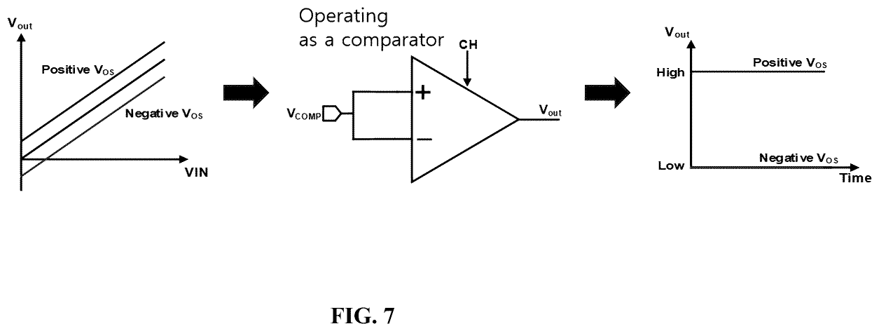

The DAC embedded amp 20 will be described with reference to FIGS. 6 and 7.

FIG. 6 is a circuit diagram of a DAC embedded amp 20 according to an embodiment of the present invention.

Referring to FIG. 6, the DAC embedded amp 20 may include an amplification stage module and an input stage module. The DAC embedded amp 20 may include an amplification stage module and an input stage module to operate as a general output buffer. This means that the DAC embedded amp includes an output buffer, and the expressions may be interchangeably used herein.

In the DAC embedded amp 20 operating as an output buffer, an offset voltage having an irregular magnitude may be generated according to a current mismatch, and each offset may have positive or negative polarity.

The amplification stage module may include at least one power supply voltage node VDD, a ground node VSS, capacitors C1 and C2, and a plurality of transistors M3 to M16. In addition, bias signals VBP1, VBP2, VBN1, and VBN2 may be applied to each transistor.

The input stage module may include an N-bit DAC embedded input stage, and at least one MUX and transistor which are input terminals of the input stage. The N-bit DAC embedded input stage may have a structure in which a plurality of transistors MN1 to MN8 are connected in parallel, and separate signals VN and VP may be input to each transistor. Here, the N-bit embedded input stage may be a 2-bit DAC built-in input stage, but is not limited thereto.

According to an embodiment, the DAC embedded amp 20 may be configured with an amplification stage module and an input stage module connected in parallel through multiple nodes. For example, as shown in FIG. 6, a first node N1, located at the opposite terminal of a transistor M3 connected to one power supply voltage node VDD, and a second node N2, located at the opposite terminal of another transistor M4 connected to the same power supply voltage node VDD, can be arranged to connect in parallel to an N-bit DAC embedded input stage. Additionally, N-bit DAC embedded input stage may be connected to the ground node VSS of the amplification stage module via at least one transistor at the opposite terminals where the first node N1 and second node N2 are connected.

According to an embodiment, the output buffer may operate as a comparator. The DAC embedded amp 20 may operate an output buffer as a comparator during an offset cancelation operation, and this may be switched by a selection signal SEL input from the outside. That is, the output buffer may operate as a comparator when the select signal SEL is 1, and may operate as an output buffer when the select signal SEL is 0.

FIG. 7 is a schematic diagram showing an output value when an output buffer in the DAC embedded amp 20 operates as a comparator according to an embodiment. When the output buffer operates as a comparator, the output buffer (comparator) may output different values Vout according to the polarity of the offset voltage. For example, when the offset voltage is a positive number (positive Vos), the output value Vout may be High(1), and when the offset voltage is a negative number (negative Vos), the output value Vout may be low(0).

In addition, according to an embodiment, the DAC embedded amp 20 may include a switch for inverting an offset polarity, and the switch for inverting an offset polarity may be controlled by the offset voltage polarity unifier 40. In detail, the DAC embedded amp 20 may include an offset polarity inversion switch in the amplification stage module, and the offset polarity inversion switch may be controlled by the switch control signals CH and CHB output from the offset voltage polarity unifier 40. Referring back to FIG. 6, it can be seen that the DAC embedded amp 20 includes an offset polarity inversion switch, and each offset polarity inversion switch can be controlled by the switch control signals CH and CHB. A detailed description thereof will be described later.

The offset voltage polarity unifier 40 will be described with reference to FIGS. 8 to 10.

FIG. 8 is a schematic diagram of an offset voltage polarity unifier 40 according to an embodiment.

The offset voltage polarity unifier 40 can unify the polarity of the offset voltage generated in the output buffer to either positive or negative. Specifically, the offset voltage polarity unifier 40 determines the polarity of the offset voltage and converts it to represent a single polarity, either positive or negative.

Referring to FIG. 8, the offset voltage polarity unifier 40 may receive an output value Vout according to the comparator operation of the output buffer, a control signal RSB, and a polarity signal SAVE_POL from the outside, and generate switch control signals CH and CHB for controlling an offset polarity inversion switch as outputs. That is, the offset voltage polarity unifier 40 receives the output value Vout of the output buffer to determine whether the offset voltage is positive or negative through the output value Vout, and generates the switch control signals CH and CHB for controlling the offset polarity inverting switch on the basis of the control signal RSB and the polarity signal SAVE_POL to unify the offset voltage generated in the output buffer into a positive or negative.

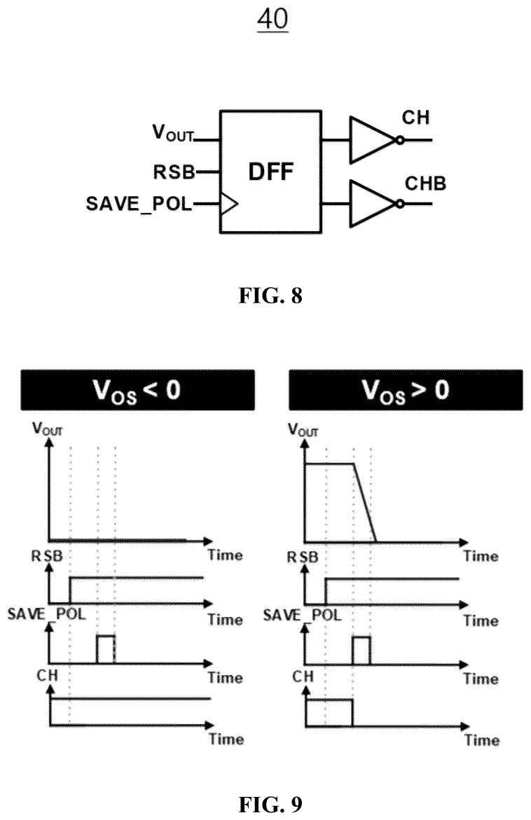

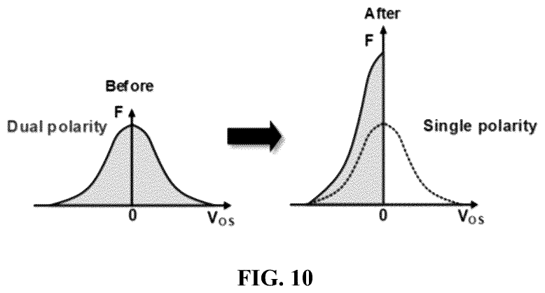

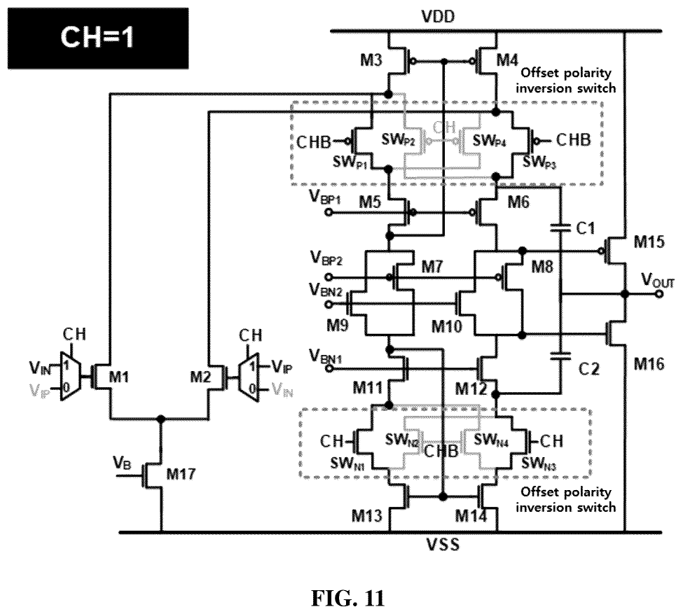

FIG. 9 is a timing diagram illustrating a process of unifying a polarity of an offset voltage according to an embodiment, and FIG. 10 is a graph illustrating a state in which a polarity of an offset voltage is unified. Referring to FIG. 9, when the control signal RSB is 0, the offset voltage polarity unifier 40 may generate the switch control signal CH=1 as an output (initial state). Thereafter, when the control signal RSB becomes 1 and the polarity signal SAVE_POL becomes 1, the switch control signal CH signal may be determined according to the polarity of the offset voltage. When the offset voltage is negative, the output value Vout is 0,and thus the switch control signal CH may be 1 (maintain an initial state). On the other hand, when the offset voltage is positive, since the output value Vout is 1, the switch control signal CH may be 0 (polarity inversion). The switch control signal CH may control an offset polarity inverting switch in the DAC embedded amp 20 to invert an offset polarity. According to the above-described example, as shown in FIG. 10, the offset voltage polarity unifier 40 may unify the offset voltage Vos generated from the output buffer into negative.

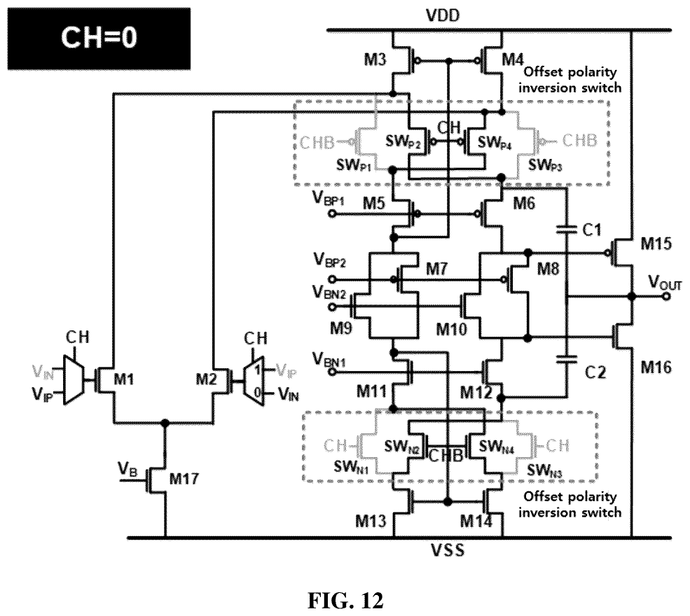

FIG. 11 and FIG. 12 are schematic diagrams illustrating a state in which an offset polarity inversion switch is controlled by a switch control signal CH. Referring to FIGS. 11 and 12, the offset polarity inversion switch is controlled based on whether the switch control signal (CH) is 1 or 0.

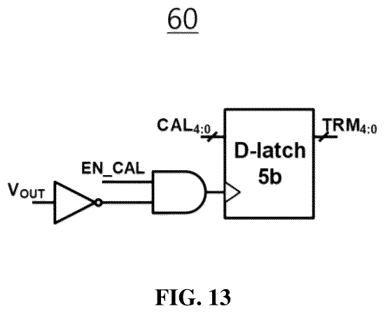

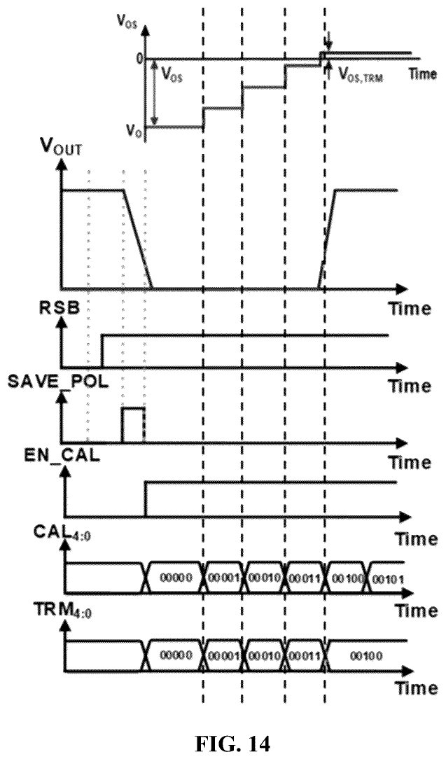

The offset calibration signal generator 60 will be described with reference to FIGS. 13 and 14.

FIG. 13 is a schematic diagram of an offset calibration signal generator 60 according to an embodiment.

The offset calibration signal generator 60 may receive a bit string signal CAL from the outside, and generate an offset calibration signal TRM based on the bit string signal CAL. In detail, the offset calibration signal generator 60 may receive an output value Vout of an output buffer, an enable signal EN_CAL, and a bit string signal CAL from the outside as inputs, and generate the offset calibration signal TRM based on the inputs. Here, the bit string signal CAL may be a 5-bit signal, but is not limited thereto.

In addition, according to an embodiment, the offset calibration signal generator 60 may receive the bit string signal CAL of which the magnitude gradually increases until the polarity of the offset voltage is inverted. For example, when the bit string signal CAL is a 5-bit signal, the offset calibration signal generator 60 may receive the smallest 00000 bit string signal CAL, and then sequentially receive the bit string signal CAL of which the size is gradually increased in the order of 00001, 00010, and 00011. The offset calibration signal generator 60 may generate the offset calibration signal TRM based on the received bit string signal CAL, and the offset compensation is performed in the offset calibration current generator 80 based thereon, and the offset compensation is also increased as the bit string signal CAL increases, so that the polarity of the offset voltage may be inverted.

According to an embodiment, the magnitude of the offset calibration signal TRM generated by the offset calibration signal generator 60 may be proportional to the magnitude of the bit string signal CAL which is a basis thereof. That is, as the magnitude of the input bit string signal CAL increases, the magnitude of the offset calibration signal TRM generated on the basis thereof may increase.

In addition, according to an embodiment, the offset calibration signal generator 60 may store, as the fixed offset calibration signal TRM-f, the bit string signal CAL at the moment when the polarity of the offset voltage is inverted as the magnitude of the bit string signal CAL increases. According to the aforementioned example, when the offset calibration signal TRM is generated based on the bit string signal CAL of 00010 and the polarity of the offset voltage is inverted from negative to positive as a result of performing the offset compensation based on the offset calibration signal TRM, the offset calibration signal generator 60 may separately store 00010 as the fixed offset calibration signal TRM-f.

A process in which the offset calibration signal generator 60 generates the offset calibration signal will be described with reference to FIG. 14.

FIG. 14 is a timing diagram of generation of a calibration signal in an offset calibration signal generator 60 according to an embodiment. FIG. 14 is an embodiment for a case where the bit string signal CAL is a 5-bit string signal.

Referring to the embodiment of FIG. 14, after the polarity is unified to negative in the offset voltage polarity unifier 40, the offset calibration signal generator 60 may receive the bit string signal CAL according to the enable signal EN_CAL. The offset calibration signal generator 60 may sequentially receive the bit string signal CAL having a size that is increased by one step in the order from the smallest 00000 to 00001 and 00010. The offset calibration signal generator 60 may generate an offset calibration signal TRM based on the bit string signal CAL, and the offset calibration current generator 80 may generate an offset calibration current based on the same, thereby compensating for the offset. As each bit string signal CAL input to the offset calibration signal generator 60 is increased step by step, the offset calibration current generated based thereon may also be increased. The offset calibration signal generator 60 may store the bit string signal CAL at the moment when the offset voltage is switched from negative to positive as the fixed offset calibration signal TRM-f according to the increased offset compensation current. In the example of FIG. 14, when the bit string signal CAL is 00100, the offset voltage is converted into positive, and 00100 may be stored as the fixed offset calibration signal TRM-f.

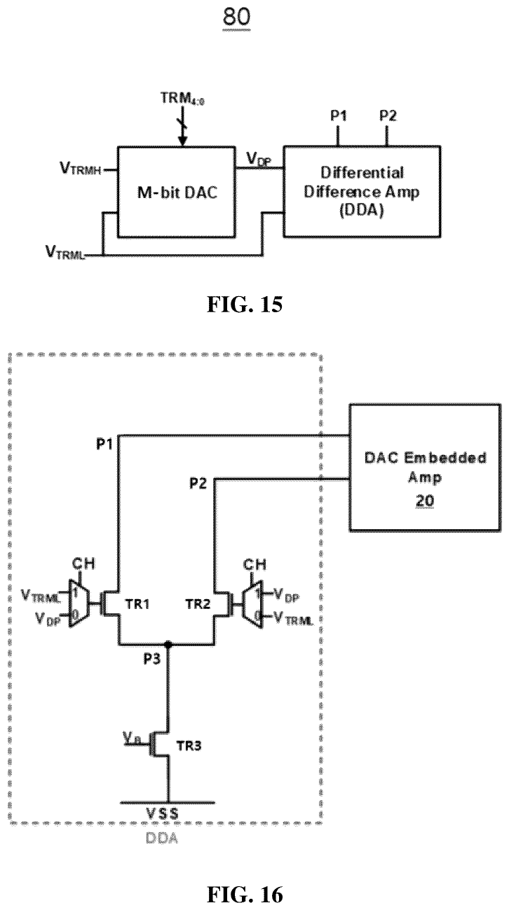

The offset calibration current generator 80 will be described with reference to FIGS. 15 to 17.

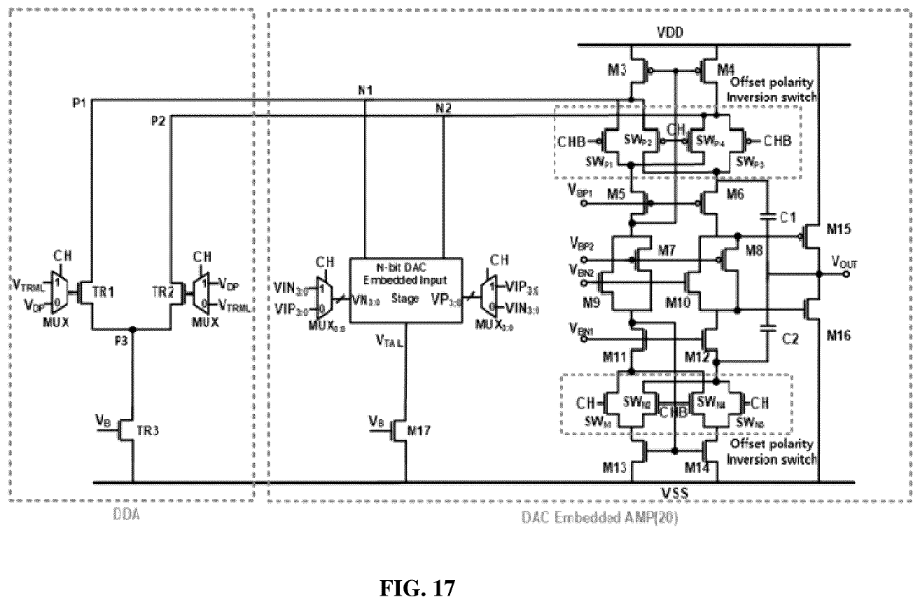

FIG. 15 is a schematic diagram of an offset calibration current generator 80, and FIGS. 16 and 17 are circuit diagrams illustrating a state in which an offset calibration current generator 80 and a DAC embedded amp 20 are connected.

Referring to FIGS. 15 to 17, the offset calibration current generator 80 may include an M-bit R-string DAC and a differential difference amp (DDA) to generate an offset calibration current. The offset calibration current generator 80 may generate an offset calibration current based on the offset calibration signal TRM generated by the offset calibration signal generator 60 and input voltages VTRMH and VTRML input from the outside. Here, the M-bit R-string DAC may be a 5-bit R-string DAC, but is not limited thereto.

Referring to FIG. 15, the M-bit R-string DAC may generate an output voltage V_{DP} using an offset calibration signal and input voltages V_{TRMH} and V_{TRML} as inputs, and the DDA may generate an offset calibration current using the output voltage V_{DP} of the M-bit R-string DAC and the input voltage V_{TRML} as inputs. In the DDA, a current difference may occur due to a difference between two input voltages V_{DP} and V_{TRML}, and an offset voltage may be compensated by using the current difference as an offset calibration current.

In addition, referring to FIGS. 16 and 17, the DDA may be provided to be connected to the DAC embedded amp 20.

Referring to FIG. 17, the DDA according to an embodiment may be provided in parallel with an input stage module through a first calibration current port P1 connected to the first node N1 and a second calibration current port P3 connected to the second node N2.

In addition, the DDA according to an embodiment may include a first transistor TR1 connected to the first calibration current port P1 and a second transistor TR2 connected to the second calibration current port P2. In addition, the first transistor TR1 and the second transistor TR2 may be connected in parallel.

In addition, in the DDA according to an embodiment, each of the first transistor TR1 and the second transistor TR2 may have a multiplexer MUX, which receives an output voltage V_{DP} and an input voltage V_{TRML} of the M-bit R-string DAC as inputs, as an input terminal. The first transistor TR1 and the second transistor TR2 may compensate for an offset voltage by using a difference between voltages V_{DP} and V_{TRML} of two input nodes as an offset calibration current.

In addition, according to FIGS. 16 and 17, in the DDA according to an embodiment, the first transistor TR1 and the second transistor TR2 may be connected to the third node P3, which is located at the opposite ends of the terminals where the first calibration current port P1 and the second calibration current port P2 are positioned. That is, a third node P3 may be positioned and connected at the other terminals of the first transistor TR1, which has a first compensation current port P1 at one terminal, and the second transistor TR2, which has a second compensation current port P2 at one terminal.

In addition, the DDA may further include a third transistor TR3 between the third node P3 and the ground node VSS. That is, the third node P3 and the ground node VSS of the amplification stage module may be connected with the third transistor TR3 interposed therebetween.

According to an embodiment, whenever the magnitude of the offset calibration signal TRM increases, a difference between voltages of two input nodes of the DDA may increase. Since the magnitude of the offset calibration signal TRM may be proportional to the magnitude of the bit string signal CAL inputted, that is, as the magnitude of the bit string signal CAL inputted increases, the difference between the voltages of the two input nodes of the DDA increases, and thus the magnitude of the offset calibration current generated may increase.

In addition, according to an embodiment, the offset calibration current generator 80 may continuously generate an offset calibration current based on the stored fixed offset calibration signal TRM-f. Referring back to the example of FIG. 14, the offset voltage may be minimized by generating the offset calibration current based on the stored fixed offset calibration signal TRM-f 00100, and the deviation of the offset voltage may be minimized by continuously generating the offset calibration current.

In addition, according to an embodiment, the M-bit R-string DAC may adjust the minimum value of the offset compensation voltage based on input voltages V_{TRMH} and V_{TRML} input from the outside. Here, the offset compensation voltage may mean a voltage for generating an offset calibration current. According to an embodiment, the minimum value of the offset compensation voltage may be (V_{TRMH}−V_{TRML})/32, but is not limited thereto.

Hereinafter, an offset calibration method according to an embodiment of the present invention will be described.

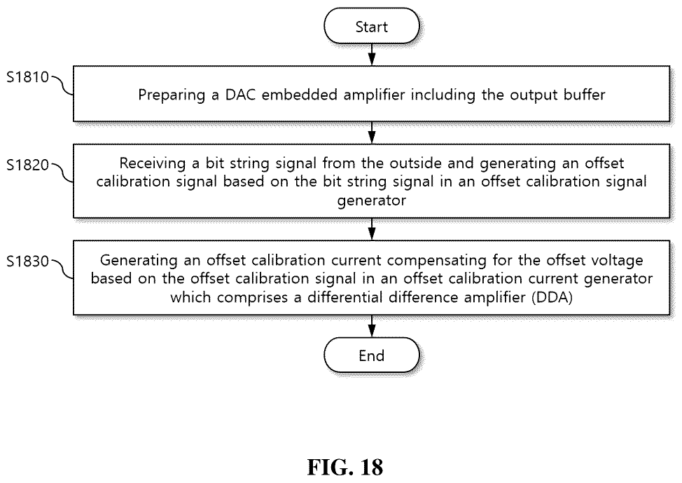

FIG. 18 is a flowchart of an offset calibration method according to an embodiment.

Referring to FIG. 18, A method for offset calibration according to an embodiment of the present invention relates to a method to compensate an offset voltage occurring in an output buffer, the method for offset calibration comprises preparing a DAC embedded amplifier including the output buffer (S1810). Also, the method for offset calibration comprises receiving a bit string signal from the outside and generating an offset calibration signal based on the bit string signal in an offset calibration signal generator (S1820). Also, the method for offset calibration comprises generating an offset calibration current compensating for the offset voltage based on the offset calibration signal in an offset calibration current generator which comprises a differential difference amplifier (DDA) (S1830).

According to one embodiment, the DAC embedded amplifier comprises an N-bit DAC embedded input stage, a first node and a second node connected to the N-bit DAC embedded input stage, and the DDA is connected in parallel with the N-bit DAC embedded input stage via a first calibration current port connected to the first node and a second calibration current port connected to the second node.

According to one embodiment, the DDA comprises a first transistor connected to the first calibration current port and a second transistor connected to the second calibration current port, wherein the first transistor and the second transistor are connected in parallel.

According to one embodiment, the DDA further comprises a third transistor positioned between ground node and third node, wherein the third node is located at the opposite ends where the first calibration current port and the second calibration current port are positioned to connect the first transistor and the second transistor.

According to one embodiment, the offset calibration current generator further comprises an M-bit R-string DAC.

According to one embodiment, the offset calibration current generator is configured to generate the offset calibration current in the DDA based on input voltage input from the outside and output voltage, wherein the output voltage is output from the M-bit R-string DAC based on the offset calibration signal and the input voltage.

According to one embodiment, the M-bit R-string DAC is configured to adjust a minimum value of an offset compensation voltage for generating an offset calibration current based on the input voltage.

According to one embodiment, the method for offset calibration further comprises unifying a polarity of the offset voltage generated from the output buffer into a positive or negative polarity in an offset voltage polarity unifier.

According to one embodiment, the generating an offset calibration signal is configured to receive the bit string signal of which the magnitude gradually increases until the polarity of the offset voltage is inverted, and stores the bit string signal at a moment when the polarity of the offset voltage is inverted as the magnitude of the bit string signal increases, as the offset calibration signal, and the generating an offset calibration current is configured to continuously generate the offset calibration current based on the stored offset calibration signal.

According to one embodiment, the DAC embedded amp further comprises a switch for inverting an offset polarity, which is controlled by the offset voltage polarity unifier.

As described above, embodiments of the present invention have been explained with reference to the accompanying drawings. However, it will be understood by those skilled in the art to which the present invention pertains that the present invention may be implemented in other specific forms without departing from the spirit or essential features of the invention. Therefore, the embodiments described above should be considered in all respects as illustrative rather than restrictive.

### DESCRIPTION OF THE SIGN

1: Apparatus for offset calibration
20: DAC embedded AMP
40: Offset voltage polarity unifier
60: Offset calibration signal generator
80: Offset calibration current generator

1. An apparatus for offset calibration to compensate an offset voltage occurring in an output buffer, the apparatus for offset calibration comprising:
a DAC embedded amplifier that includes the output buffer;
an offset calibration signal generator configured to receive a bit string signal from the outside and generate an offset calibration signal based on the bit string signal; and
an offset calibration current generator which comprises a differential difference amplifier (DDA) and is configured to generate an offset calibration current compensating for the offset voltage based on the offset calibration signal.

2. The apparatus for offset calibration of claim 1,
wherein the DAC embedded amplifier comprises:
an N-bit DAC embedded input stage, a first node and a second node connected to the N-bit DAC embedded input stage,
wherein the DDA is connected in parallel with the N-bit DAC embedded input stage via a first calibration current port connected to the first node and a second calibration current port connected to the second node.

3. The apparatus for offset calibration of claim 2,
wherein the DDA comprises:
a first transistor connected to the first calibration current port and a second transistor connected to the second calibration current port, wherein the first transistor and the second transistor are connected in parallel.

4. The apparatus for offset calibration of claim 3,
wherein the DDA further comprises:
a third transistor positioned between ground node and third node, wherein the third node is located at the opposite ends where the first calibration current port and the second calibration current port are positioned to connect the first transistor and the second transistor.

5. The apparatus for offset calibration of claim 3,
wherein the offset calibration current generator further comprises:
an M-bit R-string DAC.

6. The apparatus for offset calibration of claim 5,
wherein the offset calibration current generator is configured to generate the offset calibration current in the DDA based on input voltage input from the outside and output voltage, wherein the output voltage is output from the M-bit R-string DAC based on the offset calibration signal and the input voltage.

7. The apparatus for offset calibration of claim 6,
wherein the M-bit R-string DAC is configured to adjust a minimum value of an offset compensation voltage for generating an offset calibration current based on the input voltage.

8. The apparatus for offset calibration of claim 1,
the apparatus for offset calibration further comprising:
an offset voltage polarity unifier unifying a polarity of the offset voltage generated from the output buffer into a positive or negative polarity.

9. The apparatus for offset calibration of claim 8,
wherein the offset calibration signal generator is configured to receive the bit string signal of which the magnitude gradually increases until the polarity of the offset voltage is inverted, and stores the bit string signal at a moment when the polarity of the offset voltage is inverted as the magnitude of the bit string signal increases, as the offset calibration signal,
wherein the offset calibration current generator is configured to continuously generate the offset calibration current based on the stored offset calibration signal.

10. The apparatus for offset calibration of claim 8,
wherein the DAC embedded amp further comprising:
a switch for inverting an offset polarity, which is controlled by the offset voltage polarity unifier.

11. A method for offset calibration to compensate an offset voltage occurring in an output buffer, the method for offset calibration comprising:
preparing a DAC embedded amplifier including the output buffer;
receiving a bit string signal from the outside and generating an offset calibration signal based on the bit string signal in an offset calibration signal generator; and
generating an offset calibration current compensating for the offset voltage based on the offset calibration signal in an offset calibration current generator which comprises a differential difference amplifier (DDA).

12. The method for offset calibration of claim 11,
wherein the DAC embedded amplifier comprises:
an N-bit DAC embedded input stage, a first node and a second node connected to the N-bit DAC embedded input stage,
wherein the DDA is connected in parallel with the N-bit DAC embedded input stage via a first calibration current port connected to the first node and a second calibration current port connected to the second node.

13. The method for offset calibration of claim 12,
wherein the DDA comprises:
a first transistor connected to the first calibration current port and a second transistor connected to the second calibration current port, wherein the first transistor and the second transistor are connected in parallel.

14. The method for offset calibration of claim 13,
wherein the DDA further comprises:
a third transistor positioned between ground node and third node, wherein the third node is located at the opposite ends where the first calibration current port and the second calibration current port are positioned to connect the first transistor and the second transistor.

15. The method for offset calibration of claim 13,
wherein the offset calibration current generator further comprises:
an M-bit R-string DAC.

16. The method for offset calibration of claim 15,
wherein the offset calibration current generator is configured to generate the offset calibration current in the DDA based on input voltage input from the outside and output voltage, wherein the output voltage is output from the M-bit R-string DAC based on the offset calibration signal and the input voltage.

17. The method for offset calibration of claim 16,
wherein the M-bit R-string DAC is configured to adjust a minimum value of an offset compensation voltage for generating an offset calibration current based on the input voltage.

18. The method for offset calibration of claim 11,
the method for offset calibration further comprising:
unifying a polarity of the offset voltage generated from the output buffer into a positive or negative polarity in an offset voltage polarity unifier.

19. The method for offset calibration of claim 18,
wherein the generating an offset calibration signal is configured to receive the bit string signal of which the magnitude gradually increases until the polarity of the offset voltage is inverted, and stores the bit string signal at a moment when the polarity of the offset voltage is inverted as the magnitude of the bit string signal increases, as the offset calibration signal,
wherein the generating an offset calibration current is configured to continuously generate the offset calibration current based on the stored offset calibration signal.

20. The method for offset calibration of claim 18,
wherein the DAC embedded amp further comprising:
a switch for inverting an offset polarity, which is controlled by the offset voltage polarity unifier.
